(19) United States
(12) Patent Application Publication
(10) Pub. No.: US 2005/0011860 A1
(43) Pub. Date: Jan. 20, 2005

(54) Substrate for magnetic recording medium, method for manufacturing the same and magnetic recording medium

(76) Inventors: Masatoshi Ishii, Takefu-shi (JP); Toshihiro Tsumori, Takefu-shi (JP); Ken Ohashi, Takefu-shi (JP)

Correspondence Address: MYERS BIGEL SIBLEY & SAJOVEC, PO BOX 37428, RALEIGH, NC, 27627, US

(21) Appl. No.: 10/886,769

(22) Filed: Jul. 8, 2004

(30) Foreign Application Priority Data
Jul. 15, 2003 (JP) 2003-197118

(51) Int. Cl. B44C 1/22; C03C 25/68; H01L 21/76

(52) U.S. Cl. 216/56; 428/900; 216/88; 216/99

(57) ABSTRACT

Provided is a substrate for a magnetic recording medium, preferably a substrate having a small diameter of not more than 65 mm, which is advantageous in respect of physical properties and cost. More specifically, provided is a substrate for a magnetic recording medium, using a monocrystalline silicon wafer which has been heated and/or etched at least once before. Moreover, provided is a method for manufacturing a substrate for a magnetic recording medium, the method comprising a step of coring for obtaining a plurality of doughnut-shaped substrates having an outer diameter of not more than 65 mm from a monocrystalline silicon wafer having a diameter of at least 150 mm and at most 300 mm which has undergone heating and/or etching at least once. The method may preferably further comprise a step of chamfering for removing edges of inner and outer circumferential faces of said doughnut-shaped substrate; and a step of circumferential face-polishing for polishing the chamfered inner and outer circumferential faces.

### BACKGROUND OF THE INVENTION

1. Field of the Invention

The invention relates to a recording medium substrate for magnetic recording, and more specifically to a recording medium substrate for magnetic recording which is optimal as a small diameter substrate preferably having a diameter not more than 65 mm and more preferably having a diameter not more than 50 mm.

2. Description of the Related Art

The increase in recording density (surface density) of magnetic recording has been extremely rapid, the rapid increase over these past 10 years advancing continuously at yearly rates of 50 to 200%. At the mass production level, products with 70 Gbits/inch² are shipped, while surface recording densities twice higher, namely 160 Gbits/inch², have been reported at the laboratory level. Surface recording densities at the mass production level correspond to 80 Gbytes per one platter of a 3.5″ HDD (3.5 inch), and corresponds to 40 Gbytes per single platter of a 2.5″ HDD. At these recording volumes, installation of single platter recording media gives a sufficient volume for use in an ordinary desk top personal computer (equipped with a 3.5″ HDD) or a laptop personal computer (equipped with a 2.5″ HDD).

It is expected that recording densities will also continue to improve in the future. However, conventional horizontal magnetic recording methods are approaching their thermal fluctuation recording limit. Thus, when recording densities of 100 Gbit/inch² to 200 Gbit/inch² are reached, it is believed that it will be replaced by perpendicular magnetic recording. At the present time it is not certain what the recording limit of perpendicular magnetic recording will be, but it is believed that 1000 Gbit/inch² (1 Tbit/inch²) is achievable. If these types of high recording densities are achieved, it will be possible to obtain a recording volume of 600 to 700 Gbytes per single platter of a 2.5″ HDD.

As it is very likely that such a large volume will not be fully utilized by ordinary personal computer use, recording media having a diameter smaller than 2.5″ are gradually coming into use. Typically, there are substrates of 1.8″ or 1″, and 1.3″ HDDs was also sold in the past. HDDs of not more than 2″ have very small capacities at the present time, however if magnetic recording densities increase in the future, then a 1.8″ HDD in a personal computer (particularly in a laptop) can ensure a sufficient recording volume. Furthermore, the recording volume of a 1″ HDD is in the order of 1 to 4 Gbyte at the present, however if the volume was several times larger, many possibilities for a wide range of mobile uses would emerge, not limited just to digital cameras and the like, but also for personal computers and digital video cameras, information terminals, hand held music devices and mobile phones for example. Small diameter HDDs, small diameter recording media and substrates having diameter of not more than 2″ offer promising applications in the future.

As a substrate for the recording medium of a HDD, Al alloy substrates are mainly used for 3.5″ substrates, while glass substrates are mainly used for 2.5″ HDDs. There is a high possibility of HDDs in mobile applications, such as in laptop computers, receiving a shock. Because the possibility of data loss from scratches to the recording medium or the head resulting from head collision is large, the 2.5″ HDDs mounted in these devices have come to use very hard glass substrates. Consequently, there is also a large possibility that glass substrates will also be used in small diameter substrates of not more than 2″.

However, because small diameter substrates of not greater than 2″ are mainly used in mobile applications, shock resistance is of greater importance than for 2.5″ substrates mounted in laptop computers. Furthermore, from the need for the smaller size, there is a demand for making all parts including the substrate smaller and thinner. A thickness of the 2″ substrate board is demanded that is even thinner than the 0.635 mm standard thickness of the 2.5″ substrate. Due to the specifications required of such small diameter substrates, the demand is for substrates which are easily fabricated, which have a high Young's modulus and which have sufficient strength even though thin. Glass substrates have a number of problems on these points.

First, when the board thickness of the crystalline glass substrate which is actually used is not more than 0.635 mm, the Young's modulus is insufficient and resonance frequencies exist in the practical rotating region during rotation. Consequently, it is difficult to slim down further than this. Furthermore, although glass base plates are already used as substrates with a thickness in the 0.8 mm range, it is difficult to fabricate glass compositions which are any thinner than this, as demanded as HDD base plates. Because of this, it is necessary to adjust the thickness by lap-grinding from the 0.8 mm range down to the 0.5 mm range or even thinner. This is not preferable as it increases process costs and process time because the polishing time for width adjustment becomes very long.

Furthermore, the glass substrate is naturally a non-conductor, so there is the problem of charge up on the substrate when making films by sputtering. Thus, it is necessary to insert a metal film buffer between the substrate and the magnetic film in order to ensure favorable contact with the magnetic film. Basically, these technical problems have been solved, however this is one reason why it is difficult to use glass substrates in a sputter film forming process. Because of this, it would be ideal if it were possible to confer conductivity to the substrate, however this is difficult with glass substrates.

Just as glass substrates are mainly used even in 2.5″ HDDs, Al alloy substrates are completely unsuitable for mobile applications. It was stated previously that the hardness of the substrate is insufficient. Because substrate stiffness is also insufficient, the only way to ensure that resonance frequencies are above the actual rotating region is to increase the thickness. Thus, it is not possible to consider it as a candidate substrate for mobile applications.

A number of other substitute substrates have been proposed, such as sapphire glass, SiC substrates, engineering plastic substrates, carbon substrates and the like, however from the standard evaluations of strength, processability, cost, surface smoothness and compatibility for film deposition and the like, all are inadequate as substitute substrates for small diameter substrates.

Use of a Si monocrystalline substrate has been proposed as a HDD recording film substrate (Japanese Patent Provisional Publication No.6-176339/1994). A Si monocrystalline substrate is superior as the HDD substrate because of its excellent substrate smoothness, environmental stability and reliability, and because its stiffness is also comparatively high when compared to a glass substrates. Differing from a glass substrate, it has at least the conductivity of a semi-conductor. Furthermore, because it is generally the case that a regular wafer includes P-type or N-type dopant, the conductivity is even higher. Consequently, there is no problem with charge-up during sputter film formation as with glass substrates, and it is possible to sputter a metal film directly onto the Si substrate. Furthermore, because it has favorable thermal conductivity, the substrate is easily heated, film formation is possible even at high temperatures above 300° C. and it is excellently suited to the sputter film forming process. Si monocrystalline substrates for semi-conductor IC use are mass-produced as wafers having a diameter of 100 mm to 300 mm.

### SUMMARY OF THE INVENTION

However, it is currently difficult to obtain a small diameter wafer having a diameter of not more than 100 mm. Consequently, it is practical to cut out the desired small diameter substrate by coring from a 6″ or 8″ wafer, which is currently in most common use. However, because the price of semi-conductor grade Si monocrystalline substrate is expensive, it is at a noticeable disadvantage compared to the glass base plates or the Al base plates from a cost aspect.

The invention provides a substrate for a magnetic recording medium, preferably a small diameter substrate having a diameter of preferably not more than 65 mm, more preferably not more than 50 mm, which is advantageous with regard to physical properties and cost.

The invention provides a substrate for a magnetic recording medium using a monocrystalline silicon wafer which has been heated and/or etched at least once.

The invention also provides a method for manufacturing a substrate for a magnetic recording medium, the method comprising a step of coring, wherein a plurality of doughnut-shaped substrates having an outer diameter of not more than 65 mm and a preferable inner diameter of not more than 20 mm, a more preferable inner diameter of not more than 12 mm, are obtained by coring of a monocrystalline silicon wafer having a diameter of at least 150 mm and at most 300 mm which has undergone heating and/or etching at least once. The method may preferably further comprise a step of chamfering wherein edges of inner and outer circumferential faces of said doughnut-shaped substrate are removed; and a step of circumferential face-polishing wherein the chamfered inner and outer circumferential faces are polished (or ground). The method may preferably comprise a step of lapping wherein 10 μm to 100 μm is removed by polishing (or grinding) from a surface of the monocrystalline silicon wafer or the doughnut-shaped substrate, preferably before or after the step of coring. The step of lapping may be comprised, for example, preferably before the step of coring, between the steps of coring and chamfering, between the steps of chamfering and circumferential face-polishing, or after the step of circumferential face-polishing. The step of lapping may be comprised more preferably before the step of coring, between the steps of chamfering and circumferential face-polishing, or after the step of circumferential face-polishing.

According to the invention, a silicon monocrystalline substrate is provided that is appropriate for a substrate for a HDD magnetic recording medium. The substrate is advantageous from the aspect of physical properties and cost.

### BRIEF DESCRIPTION OF THE DRAWING

FIG. 1 shows a scheme of one example for producing a substrate for a HDD magnetic recording medium, using a silicon monocrystalline wafer as a base plate.

### DETAILED DESCRIPTION OF THE PREFERRED EMBODIMENTS

The invention relates to a substrate for a HDD magnetic recording medium comprising a Si monocrystalline substrate having a diameter of not more than 65 mm (the diameter described here is the nominal diameter) which is fabricated by a coring process from a silicon monocrystalline wafer which has undergone thermal treatment and/or etching at least once; and a method for manufacturing the same.

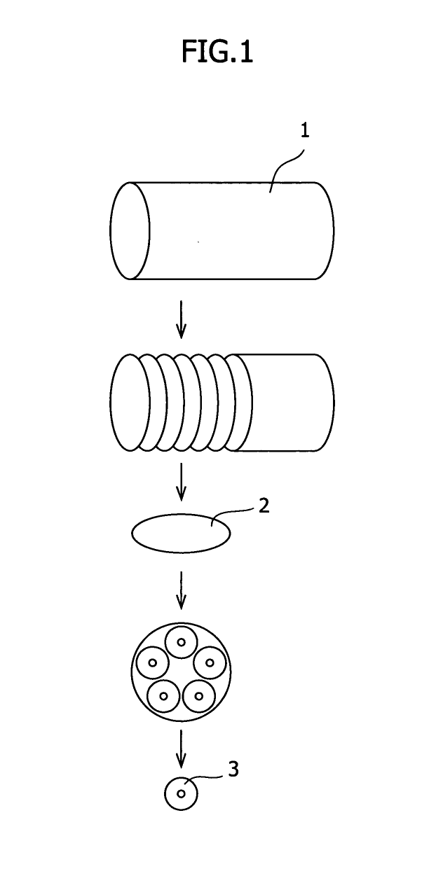

FIG. 1 shows a scheme of one example for producing a substrate for a HDD magnetic recording medium, using a silicon monocrystalline wafer as a base plate.

A monocrystalline silicon rod 1 is sliced to produce monocrystalline silicon wafers 2 having a diameter of 200 mm and cored to obtain doughnut-shaped wafers 3 having an outer diameter of 65 mm. According to a method disclosed in Japanese Patent Provisional Publication No. 10-334461/1998, seven cores of HDD substrates having a diameter of 65 mm can be obtained from a 200 mm monocrystalline silicon wafer. The edges of inner and outer circumferential faces of the doughnut-shaped substrate 3 may be preferably removed and the circumferential faces are polished. Subsequently, the small diameter substrate may be produced typically by a step of alkali etching, a step of polishing both surfaces and a step of washing.

A step of lapping for grinding off preferably 10 μm to 100 μm of the surface of the monocrystalline silicon wafer or the doughnut-shaped substrate may be comprised before or after the step of coring, for example before the step of coring, between the step of coring and the step of chamfering, between the step of chamfering and the step of circumferential face-polishing, or after the step of circumferential face-polishing. The step of lapping may be more preferably comprised before the step of coring, between the step of chamfering and the step of circumferential face-polishing, or after the step of circumferential face-polishing.

The monocrystalline silicon wafer used in the step of coring may preferably have a surface orientation of (1 0 0), an outer diameter of at least 150 mm and at most 300 mm and have a thickness of 0.4 mm to 1 mm (more preferably 0.7 mm or less).

Semiconductor grade silicon monocrystalline wafers (prime wafers) are very expensive, so if a 65 mm diameter substrate is fabricated using a monocrystalline base plate, it will cost from a few times closely to ten times the cost of a glass substrate. No matter how much better the characteristic properties of the silicon monocrystalline substrate are, just this cost difference alone makes it difficult to put these to practical use.

On the other hand, a silicon monocrystalline monitor wafer of the same diameter is used for the purpose of monitoring the steps in the semiconductor IC process. The ratio of monitor wafers to prime wafers may approach 1:1 when starting a new diameter substrate or a process thereof. Although the quality of monitor wafers is not inferior to that of the prime wafers, they are slightly inexpensive. Use of monitor wafers in the manufacturing process of semiconductor ICs is unavoidable, it is difficult to use the desired number of the substrates in substrates for HDDs, and there is no big cost reduction even at the price of the base plates.

In addition to prime wafers and monitor wafers, dummy wafers (or recycled wafers) are used as the Si monocrystalline substrate in the semiconductor IC process. Dummy wafers are re-used at least once for the purpose of checking or investigating the process. Monitor wafers which have been used once and which have had their oxide layer or metal layer scraped off are recycled wafers. Although obvious, the price of substrates is in the sequence of prime wafers>monitor wafers>recycled wafers. Recycled wafers are ordinarily used at least once, up to the order of 5 to 6 times, and the variety of adherent films on the upper surface is polished off each time they are used. Because the recycled wafer is gradually ground away, it becomes thinner by an order of 10 μm to 100 μm with each use. Because recycled wafers which have become thinner than a standard thickness value become unsuitable for the purpose of checking the process, they are disposed of without further use. There are a variety of standard thicknesses, but generally they may be discarded once their thickness reaches 0.7 mm to 0.5 mm or less.

Because recycled wafers are used many times over, they experience a variety of steps in the semiconductor process. Consequently, because each wafer also acquires a variety of thermal histories, various types of ion implantations, dopants and electrical resistances and the like, it become unsuitable for use in solar battery applications and the like so that it is usually discarded.

In silicon monocrystalline substrates for HDDs, the thermal history of the monocrystalline wafer base plate, or the type of dopants used or the like are not important. Irrespective of N-types or P-types, as long as it has at least the conductivity of a semiconductor it is applicable. It is important that it is a monocrystal which has no grain boundary on the polished face. As a HDD substrate, the important points are surface smoothness after polishing, and the strength required for the substrate. There is no change to the fact that recycled wafers are still silicon monocrystals, so there is absolutely no problem with surface smoothness after polishing.

Because recycled wafers have been heated at least once, the substrate strength may be reduced due to crystal defects or dislocations at the atomic level, or by micro-scratches or micro-cracks when the HDD substrate is processed. However, it has been found that as long as these defects do not exist at the substrate surface, on the contrary the strength of the substrate becomes stronger. The reason for this is not clear, however it appears that dissolved oxygen links with one portion of the silicon and behaves as a supporting member. Thus, it is possible to use discarded recycled wafers having less than a predetermined thickness as a relatively low cost HDD base substrate.

The invention provides a method for manufacturing a substrate for a magnetic recording medium comprising a step of coring wherein a plurality of doughnut-shaped substrates having an outer diameter of not more than 65 mm are obtained by coring of a monocrystalline silicon wafer having a diameter of at least 150 mm and at most 300 mm which has undergone heating and/or etching at least once before, and preferably, a step of chamfering of the inner and outer circumferential faces of the doughnut-shaped substrate and a step of circumferential face-polishing.

The monocrystalline silicon wafer having a diameter of at least 150 mm and at most 300 mm which has undergone heating and/or etching at least once before includes recycled wafers and used monitor wafers, excluding prime wafers.

The monocrystalline silicon wafer which has undergone heating at least once may include, for example, wafers that have been heat treated (for example at 400 to 1350° C.) once as monitor wafers, and wafers that have been heat treated at least twice as recycled wafers.

A monocrystalline silicon wafer which has undergone etching at least once, may include for example wafers that have undergone various types of etching once in the semiconductor manufacturing process as monitor wafers, and wafers that have been etched at least twice as a recycled wafer.

In the step of coring, a plurality of substrates having an outer diameter of not more than 60 mm can be obtained from a monocrystalline silicon wafer having a diameter of at least 150 mm and at most 300 mm, using for example cup grinder processing, laser processing with a CO₂ laser or a YAG laser or the like, water jet processing using high pressure water mixed with abrasive material, or blast processing.

The step of coring may comprise outer diameter coring (outer circumferential coring) and inner diameter coring (inner circumferential coring).

In the case of cup grinder processing, it may be more efficient to carry out the outer diameter coring following the inner diameter coring, wherein the inner diameter core portion is used as a hold-down hole during the outer coring. It is because, for example, only the material that has passed a predetermined inspection after the inner diameter coring can be subjected to the outer diameter coring process. However, the reverse sequence of procedure is also possible.

According to the invention, it is preferable to also provide a step of lapping to polish off 10 μm to 100 μm, for example before or after the step of coring of the recycled wafer. The step of lapping after the step of coring may be provided, for example, between the step of coring and the step of chamfering, between the step of chamfering and the step of circumferential face-polishing, or after the step of circumferential face-polishing. The step of lapping may be provided preferably between the step of chamfering and the step of circumferential face-polishing, or after the step of circumferential face-polishing.

It is mostly possible to remove pits and defects from the surface of the wafer base plate in the lapping step. It has been found that if the pits and defects are able to be removed, there is no effect on substrate strength. Defects and pits originating from the various semiconductor processes undergone by the recycled wafer are confined to a portion extremely close to the surface, so these can be mostly removed by lapping away 10 μm to 100 μm off the surface. The thickness of a 200 mm monitor wafer is 0.835 mm, and the thickness of a discarded recycled wafer is 0.6 to 0.7 mm. Because the standard thickness of a 65 mm substrate is 0.635 mm, it is desirable that the HDD substrate of the invention is applied to small diameter substrates of not more than 65 mm.

Furthermore, according to the invention, there is a reason why the layer to be polished off for the removal of defects can be comparatively thin. Although a HDD substrate uses both surfaces, a semiconductor wafer basically uses only a single surface. Accordingly, a rear surface gets by without undergoing various processes (other than heating). Consequently, damage to the rear surface is comparatively light so that it is possible to concentrate on removal of defects from the used surface of the recycled wafer. The majority of defects which cause a loss of strength are removable by lapping 10 to 100 μm. However, it could be a problem if crystal defects or dislocations (the defect frequency is greater than in the prime wafers or the like) existing within the internal portion appear on surfaces. After polishing both surfaces of the etched wafer following coring, defects on the surfaces of the HDD substrate for causing a problem of decreased substrate strength can be removed on basis of inspection of the highly mirror finished surfaces. Hence, the problem is with defects which exist on the circumferential faces.

In the fabrication of the HDD substrate shown in FIG. 1, a step of chamfering of the inner and outer circumferential faces and a step of the circumferential face-polishing may be provided after the step of coring of the recycled wafer base plate.

The angle and dimensions for the chamfering may be for the most part restricted to standard dimensions. When prime wafers or monitor wafers are used as the base plate, the chamfering can result in a finished product. However, when using the recycled wafers of the invention as the base plates, internal defects and the like which appear on the circumferential faces may work to cause a reduction in substrate strength. The circumferential face means the inner or outer circumferential lateral surface of the doughnut-shaped substrate. Defects which appear on the circumferential faces after the chamfering become a problem because they may become starting points of substrate destruction. Providing the step for removing distorted layers by etching after the step of circumferential face-polishing following the step of chamfering, the inventors have found that the substrate strength at a level equivalent to that of monitor wafers can be ensured even when using recycled wafer base plates.

After the step of circumferential face-polishing, or after the step of lapping following the step of circumferential face-polishing, it may be preferable that the substrate undergoes further steps including a step of alkali etching, a step of polishing the upper and lower surfaces of the substrate that has been alkali-etched, and a subsequent step of washing.

The step of alkali etching for removing the deformations caused by the steps of lapping and of circumferential face-polishing, may be carried out by dipping in a 2 to 60 weight % aqueous solution of sodium hydroxide at 40 to 60° C. for example.

The step of polishing the upper and lower faces of the alkali-etched substrate can be carried out favorably in a method known in the art. For example, a substrate mounted in a carrier between an upper plate and a lower plate are clasped, rotated and polished with colloidal silica as the polishing particles.

The step of washing can be carried out by brush washing and/or a chemical washing using an alkali and/or an acid solution, which is known in the art,

The substrate for a magnetic recording medium of the invention can be treated in the same way as a conventional substrate. For example, a soft magnetic layer and a recording layer can be disposed on the substrate so as to be used as a perpendicular magnetic recording medium. To increase adhesion of the soft magnetic layer a primer layer can be formed prior to forming the soft magnetic layer.

A protective layer and a lubricating layer can be formed above the recording layer.

The invention will be explained based on examples below, however the invention is not limited to them.

An overview of examples is given below.

A silicon monocrystalline wafer has surface orientation of (100) and a diameter of 200 mm. The silicon monocrystalline wafer which has been heated and/or etched in a semiconductor IC process or the like, is lapped for removing 10 μm to 100 μm using abrasive particles so that pits and defects are removed. Next, doughnut-shaped circular substrates having an outer diameter of not more than 65 mm are cut out from the wafer by laser light from a laser light generating device, forming a plurality of substrates. Next, the edges of the inner and outer circumferential faces of the substrates are removed by a grindstone. The upper and lower faces of the substrate are polished after alkali etching so that the desired substrates are obtained. Finally, polishing material that has adhered to the substrate is removed in the step of washing so that production of the substrate is completed.

### EXAMPLE 1

A wafer having a thickness of 0.61 mm and an outside diameter of 200 mm which had been subjected to heating up to 1000° C. four times was prepared. After removal of 50 μm by lapping, a doughnut-shaped circular substrate having a diameter of 48 mm and an inner diameter of 12 mm was obtained by a YAG laser processing device. Next, the edges of the inner and outer circumferential faces of the substrate were removed by a grindstone (diamond) and the circumferential faces were polished. After alkali etching in a 50 wt % NaOH solution at 50° C. for 20 minutes, both surfaces of the substrate were polished with 5 wt % colloidal silica until the mirror surface appears. Next, the polishing material and the like which adhered to the substrate was removed in the step of washing so that the magnetic recording medium substrate was obtained. Compressive destructive strength was measured by mounting the substrate for magnetic recording medium on a circle end of a 45 mm diameter pipe, placing a 30 mm diameter Zr ball on the substrate above the center of the pipe and adding a load from top of the ball to the substrate using a load cell. It was 500 N for average of five samples.

### EXAMPLE 2

Apart from a lapping for removing 100 μm, processing was the same as in Example 1. When compressive destructive strength was measured, it was 550 N for average of five samples.

### EXAMPLE 3

A wafer having a thickness of 0.55 mm and an outside diameter of 200 mm which had been heated up to 1000° C. six times and etched four times was prepared. After removal of 100 μm by lapping, a doughnut-shaped circular substrate having a diameter of 26 mm and an inner diameter of 7 mm was obtained by a YAG laser processing device. Next, the edges of the inner and outer circumferential faces of the substrate were removed with a grindstone (diamond). After inner and outer circumferential face-polishing and alkali-etching in a 50 wt % NaOH solution at 50° C. for 20 minutes, both surfaces of the substrate were polished with 5 wt % colloidal silica until the mirror surface appears. Next, the polishing material and the like which adhered to the substrate was removed in the step of washing so that the substrate for a magnetic recording medium was obtained. The compressive destructive strength was measured by mounting the substrate for a magnetic recording medium obtained on a 20 mm diameter pipe, and arranging a 10 mm diameter Zr ball on its inner circumferential side. It was 70 N for average of five samples.

### COMPARATIVE EXAMPLE 1

A wafer having a thickness of 0.74 mm and which had not undergone heating or etching was prepared. After lapping for adjusting the thickness and surface with abrasive particles, a doughnut-shaped circular substrate having a diameter of 48 mm and an inner diameter of 12 mm was obtained by a YAG laser processing device. Next, the edges of the inner and outer circumferential faces of the substrate were removed with a grindstone (diamond). After inner and outer circumferential face-polishing and alkali etching in a 50 wt % NaOH solution at 50° C. for 20 minutes, both surfaces of the substrate were polished with 5 wt % colloidal silica until the mirror surface appears. Next, the polishing material and the like which adhered to the substrate were removed in the step of washing so that the substrate for a magnetic recording medium was obtained. The compressive destructive strength was measured by mounting the substrate for the magnetic recording medium on a 45 mm diameter pipe, and arranging a 30 mm diameter Zr ball on its inner circumferential side. It was 300 N for average of five samples.

### COMPARATIVE EXAMPLE 2

Apart from processing to a doughnut-shaped substrate having a diameter of 26 mm and an inner diameter of 7 mm, processing was the same as Comparative Example 1. The compressive destructive strength was measured by mounting the substrate for a magnetic recording medium on a 20 mm diameter pipe, and arranging a 10 mm diameter Zr ball on its inner circumferential side. It was 50 N for average of five samples.

As given above, it has been found that high strength can be obtained at favorable efficiency when the substrate for a magnetic recording medium is fabricated using a wafer which has undergone heating and/or etching.

1. A substrate for a magnetic recording medium, comprising a monocrystalline silicon wafer which has been heated and/or etched at least once before.

2. A method for manufacturing a substrate for a magnetic recording medium, the method comprising:
a step of coring for obtaining a plurality of doughnut-shaped substrates having an outer diameter of not more than 65 mm from a monocrystalline silicon wafer having a diameter of at least 150 mm and at most 300 mm which has undergone heating and/or etching at least once.

3. The method for manufacturing a substrate for a magnetic recording medium according to claim 2, further comprising:
a step of chamfering for removing edges of inner and outer circumferential faces of said doughnut-shaped substrate;
a step of circumferential face-polishing for polishing the chamfered inner and outer circumferential faces; and
a step of lapping for removing 10 μm to 100 μm by grinding from a surface of the monocrystalline silicon wafer or the doughnut-shaped substrate, before the step of coring, or between the steps of coring and chamfering, or between the steps of chamfering and circumferential face-polishing, or after the step of circumferential face-polishing.

4. The method for manufacturing a substrate for a magnetic recording medium according to claim 2 wherein said monocrystalline silicon wafer used in said step of coring has a surface orientation of (1 0 0) and a thickness of not more than 0.7 mm.

5. The method for manufacturing a substrate for a magnetic recording medium according to claim 3, further comprising after said step of circumferential face-polishing, or after said step of lapping performed after said step of circumferential face-polishing:
a step of alkali-etching the substrate;
a step of polishing both surfaces of the alkali-etched substrate; and
a subsequent step of washing.

6. A perpendicular magnetic recording medium comprising said substrate of claim 1.

7. The method for manufacturing a substrate for a magnetic recording medium according to claim 3 wherein said monocrystalline silicon wafer used in said step of coring has a surface orientation of (1 0 0) and a thickness of not more than 0.7 mm.
